(19) United States
(12) Patent Application Publication
(10) Pub. No.: US 2010/0308345 A1
(43) Pub. Date: Dec. 9, 2010

(54) LIGHT SENSING SYSTEM

(76) Inventors: Christopher James Brown, Oxford (GB); Benjamin James Hadwen, Oxford (GB)

Correspondence Address: MARK D. SARALINO ( SHARP );RENNER, OTTO, BOISSELLE & SKLAR, LLP, 1621 EUCLID AVENUE, 19TH FLOOR, CLEVELAND, OH, 44115, US

(21) Appl. No.: 12/525,911

(22) PCT Filed: Feb. 6, 2008
(86) PCT No.: PCT/JP2008/052379

§ 371 Date: Aug. 5, 2009

(30) Foreign Application Priority Data
Feb. 7, 2007 (GB) 0702346.8

(51) Int. Cl. H01L 27/144; H01L 31/105; H01L 31/12

(52) U.S. Cl. 257/82; 250/208.2; 257/458; 257/E31.061; 257/E33.077

(57) ABSTRACT

A light sensing system comprises a first light sensor (21′), a second light sensor (21) and a first light shielding material (24) disposed over the first light sensor (21′) but not over the second light sensor (21) so as to block ambient light from being incident on the first light sensor (21). A first electrically conductive material (23a) is disposed between the first light shielding layer (24) and the first light sensor and a second electrically conductive material (23b) is disposed over the second light sensor. The second electrically conductive material (23b) is at least partially light-transmissive. Providing the first electrically conductive material (23a) between the first light shielding layer (24) and the first light sensor eliminates any parasitic capacitance that would otherwise be set up by the light shielding layer (24) (which is typically a metallic layer). Providing the second electrically conductive material (23b) over the second light sensor ensures that the two light sensors are as closely electrically matched to one another as possible. Thus, a difference between the output of the first light sensor and the output of the second light sensor may reliably be taken as an indication of the level of ambient light. The first electrically conductive material (23a) and the second electrically conductive material (23b) may be provided by disposing a layer of electrically conductive material, which is at least partially light-transmissive, so as to cover both light sensors.

### TECHNICAL FIELD

The present invention relates to a light sensing system, for example for use as an ambient light sensor or for sensing an optical input signal. Such sensors are used, for example, with an Active Matrix Liquid Crystal Display (AMLCD).

### BACKGROUND ART

An AMLCD may, for example, be a transmissive display that is illuminated by a backlight placed on the opposite side of the display to an observer. An AMLCD may alternatively be a transflective display which may be illuminated by a backlight in low ambient lighting conditions or by reflected ambient light in bright ambient lighting conditions. In both cases it is desirable to control the intensity of the backlight in dependence on the ambient lighting conditions, so that an image displayed on the AMLCD is always clearly visible to an observer but is not uncomfortably bright. A further consideration is that, particularly in the case of an AMLCD incorporated in a mobile device such as a mobile telephone, it is highly desirable to reduce the power consumption of the backlight so as to maximise battery life. Accordingly, in the case of a transflective display, the backlight is preferably operated at a low intensity in very low ambient lighting conditions, operated at a higher intensity in medium ambient lighting conditions to ensure that an image remained visible to an observer, and switched off in ambient lighting conditions that are bright enough to provide a displayed image using only reflected ambient light.

It is therefore known to provide a mobile AMLCD device with an Ambient Light Sensor (ALS) system, as shown in FIG. 1, and to control the power level of the backlight in dependence on the output of the ALS system. The AMLCD device 1 consists of a display pixel matrix 2 (on which an image is displayed), display gate driver circuitry 3, display source driver circuitry 4, a display controller 5, a backlight 6, a backlight controller 7, an Ambient Light Sensor (ALS) system 8, and an ALS controller 9. In FIG. 1 the display pixel matrix 2, the display gate driver 3, the display source driver 4 and the ALS 5 are provided on a display substrate 10 which may be, for example, a TFT substrate.

In operation the display pixel matrix 2 operates to display images in the normal way, being driven by the gate and source drive circuitry 3,4 under the control of the display controller 5. The light source for the display is the backlight 6, which is typically an array of white LEDs which are driven and controlled by the backlight controller 7.

The ALS system 8 detects the ambient light level incident upon the AMLCD device 1 and provides, at periodic intervals of time, an output to the ALS controller 9. The ALS controller 9 communicates with the backlight controller 7, which in turn controls the intensity of the backlight 6 according to the output from the ALS system 8. Consequently this arrangement is capable of adjusting the brightness of the image displayed according to the ambient lighting intensity.

In order to be able to detect the full range of ambient lighting conditions from bright sunlight to near darkness, such an ALS system requires a high dynamic range and this necessitate detection of low light levels across a wide operating temperature range. Typically, an ALS system is required to be sensitive over a wide range of incident light levels and the typical operating temperature range of a mobile LCD device.

It is also known to provide an AMLCD device such as, for example a personal digital assistant (PDA) with an optical sensor to allow a user to enter information to the PDA using a light pen. Such an AMLCD is shown in FIG. 2(a).

The AMLCD 1 of FIG. 2(a) is provided with a matrix of light sensors in the pixel matrix 2. The light sensors may, for example, be photodiodes, as indicated in FIG. 2(b) which shows the circuit for one pixel of the pixel matrix 2. (FIG. 2(b) shows a full colour pixel, having red, green and blue sub-pixels each with a respective liquid crystal element CLCr, CLCg and CLCb controlled by a respective pixel switch transistor M3r, M3g, M3b.) The AMLCD 1 is provided with a sensor row driver 11 for driving the light sensors, and a sensor read-out driver 12 for determining which sensor(s) are illuminated by a user input. The output from the sensor read-out driver 12 allows the location, on the pixel matrix 2, of a user input to be determined.

Conventional light sensor systems, for application as ambient light sensors or image sensors, may employ either discrete or integrated photodetection elements. In the case of discrete photodetection elements, the process technology for manufacturing the element is optimised for maximising the sensitivity of the device, but additional manufacturing steps are required to provide an AMLCD with lights sensors. In the case of integrated photodetection elements, such as on a CMOS IC (complementary metal-oxide-semiconductor integrated circuit), the processing technology is a compromise between maximising the sensitivity of the photodetection element and maximising the performance of the peripheral circuitry.

In the case of an AMLCD with a monolithically integrated light sensor circuits, the basic photodetection device used must be compatible with the TFT process used in the manufacture of the display substrate. A well-known photodetection device compatible with the standard TFT process is the lateral, thin-film, polysilicon p-i-n diode, the construction of which is shown in FIG. 5. In brief, in the manufacture of a polysilicon p-i-n diode 21 a base coat (BC) is deposited over a substrate 13 such as a glass substrate. A polysilicon layer is deposited over the base coat, and is patterned to leave regions 14 of polysilicon where it is desired to form a photodiode. An n-type dopant is implanted into one part 14a of the polysilicon region, and a p-type dopant is implanted into another part 14c of the polysilicon region, to obtain a region of n-Si and a region of p-Si separated by a region 14b of intrinsic silicon. A gate insulating layer (GI) and an interlayer insulator (IL) are deposited over the polysilicon region 14, and holes are made through the gate insulating layer and the interlayer insulator to allow electrical contacts 15 to be made to the n-Si region and to the p-Si region.

FIG. 5 also shows a thin film transistor 22. This is generally similar to the p-i-n diode, except that a gate electrode (GE) is deposited over the gate insulating layer, over the region 14b of intrinsic Si. In the TFT, the contacts 15 to the n-Si region and to the p-Si region constitute the source electrode (SE) and drain electrode of the TFT respectively.

FIG. 4 illustrates the TFT of FIG. 5 incorporated in an AMLCD. FIG. 4 is a cross-section through a pixel of the AMLCD, and illustrates an AMLCD in which a pixel contains a reflective part and a transmissive part. In brief, a resin layer 16 is deposited over the TFT structure shown in FIG. 5 and is planarised (the resin layer 16 is present only in the reflective part of the pixel, and is not present in the transmissive part of the pixel). Contacts holes (not shown in FIG. 4) are made through the resin layer 16 to the electrodes SE, GE of the TFT.

A transparent electrode layer (ITO), for example an indium tin oxide (ITO) layer is deposited over the resin layer 16 and over the exposed regions of the interlayer insulator IL where no resin is present. A reflective layer, for example a metallic layer is then deposited over the part of the ITO layer that overlies the resin layer 16 to form a reflective pixel electrode (RE). The reflective layer is not deposited over the part of the ITO layer that overlies the exposed regions of the interlayer insulator IL where no resin is present, and this part of the ITO layer forms a transmissive pixel electrode. The result is an active matrix substrate 17, having a matrix of pixel electrodes, each pixel electrode provided with a respective TFT for controlling the applied voltage.

A counter substrate 18 is prepared by disposing a transparent counter electrode, for example an ITO layer, a colour filter array (CF) and a black mask (BM) over another transparent substrate 13′. The TFT substrate 17 and the counter substrate 18 are then assembled together, and filled with a liquid crystal material (LC).

FIG. 3 is a block flow diagram listing the principal manufacturing steps of the AMLCD of FIG. 4.

The detailed operation of a p-i-n photodiode (which is described in numerous textbooks and papers) is somewhat complicated. In brief, however, the chief concern with photodiodes fabricated in a polysilicon TFT process is that they have a much lower sensitivity than photodiodes fabricated in bulk technologies (such as CMOS). This is for two principal reasons:
1. Firstly the volume of semiconductor material that is photosensitive (the device's depletion region) is generally quite small. In particular the depth of the thin film layer of material is typically designed to be only a few tens on nanometres, and as a result a large fraction of the illuminating radiation passes straight through the device unabsorbed and therefore undetected.
2. Secondly the dark current generated by thin film devices tends to be higher than in bulk devices. The dark current, defined as the diode leakage current under the condition of no illumination, is highly dependent both on temperature and the electric field across the device.

Additionally, photodiodes fabricated using a TFT manufacturing process will exhibit a large variation in their electrical and optical characteristics due to variations in the processing conditions. In general, the relative physical location between two devices determines the level of variation in their characteristics. Therefore, adjacent devices are more likely to be better matched than two devices located far away from each other and much better matched than devices on two separate AMLCD panels.

Another concern when using a photodiode as a light sensor within an AMLCD is the minimisation of unwanted, stray light incident on the device. Such stray light may originate from the display backlight and couple into the photodiode device by reflections within the glass substrate or from surrounding structures.

Obtaining an accurate, absolute measure of incident light intensity from a single photodiode within an AMLCD therefore requires a knowledge of the exact temperature and bias conditions, process conditions and amount of stray light entering the device.

US Patent Application No. 2005/0045881 describes a thin-film polysilicon p-i-n photodiode structure for use in a display with optical input function. The photodiode structures described include a gate metallization layer above the photodiode intrinsic region, to block hydrogen atoms from entering the region during a hydrogenation process. Hydrogenation provides a means of terminating the dangling bonds in the polysilicon thin-film and thus reducing the TFT leakage current. However, in a photosensor device, the dangling bonds should remain un-terminated in order to maximise the photoelectric conversion efficiency. As described in this document, the length of the gate electrode is intimately related to the hydrogenation process such that, for small gate lengths, hydrogen atoms diffuse from the gate edge into the region beneath the gate layer. However, for large gate lengths, the hydrogen atoms are unable to diffuse completely into the region. The gate metallization layer thus provides a means of creating both low-leakage TFT devices (having small gate length) and efficient photodiodes (having a long gate length) in the same process. Further, since the length of the gate electrode is intimately related to the photoelectric conversion efficiency of the photodiode, devices with different gate lengths will produce different photocurrents in similar conditions. A differential reading that is free from the effects of temperature and process variation may therefore be obtained by using two photodiodes of different lengths. A disadvantage with this method of compensation however, is that photodiodes of different length are not electrically equivalent having, for example, different internal electric fields and different parasitic capacitances. The dark leakage current will consequently differ between the two devices.

FIG. 6 shows a basic concept of U.S. Patent Application No. 2005/0045881, which describes a thin-film polysilicon photodiode structure incorporating a light shield consisting of both a gate metallization layer 19 and a source metallization layer 15′. In the photodiode structure of FIG. 6, the silicon region 14 comprises an n+ region 14a, an n− region 14d (doped n-type, but less heavily doped than the n+ region 14a), a photosensitive p− region 14e, and a p+ region 14c. The gate metallization layer 19 is used both as a light shield and to control hydrogenation in the photosensitive p− region 14e as described above. A light shield for the photodiode n− region 14d is created by extending the metallization 15 used for photodiode cathode contact so that it extends over the n− region 14d.

FIG. 7, taken from EP1511084, shows a similar device that additionally includes a further light-shading layer 20 beneath the photodiode. The purpose of this light-shading layer 20 is to block light from the display backlight from entering the photodiode.

JP Patent Application JP2005-132938 describes an ambient light sensor circuit, shown in FIG. 8, incorporating two photodiodes 21,21′: one photodiode 21 is exposed to ambient light and has no gate structure (the “light” structure); the other photodiode 21′ (the “dark” structure) has a gate structure to block incoming ambient light from reaching the active region. The purpose of these two devices is to allow the effects of temperature and stray light to be compensated for, an essential step in producing an ambient light sensor which outputs an accurate absolute reading of ambient light intensity. The theory is that changes in temperature, or stray light, will affect both photodiodes equally, so that any difference between the output of the “light” photodiode and the output of the “dark” photodiode must arise from the ambient light (which is incident only on the “light” photodiode and is not incident on the “dark” photodiode). For example, the ambient light sensor circuit disclosed in this document is arranged to output a differential signal comprising the difference between the outputs of the two photodiodes. Without such compensation, a significant systematic error will arise due to temperature variations, which—for a given illumination level—directly cause a variation in photodiode current and/or to stray light, for example from the display backlight. Additionally, the variation in processing conditions from panel to panel render a measurement of the absolute light intensity more difficult still. The use of a dark photodiode structure and a differential circuit method can reduce the magnitude of the variation problem from one of inter-panel variation (i.e. between panels from different manufacturing batches) to one of intra-panel variation (i.e. between two devices located close together on one panel). The circuit of FIG. 8 is described in more detail below.

US 2005/0275616 also discloses a display device having two photosensors. The display device has a backlight unit; one photosensor measures both ambient light and light from the backlight unit, and the other photosensor is shielded from ambient light and so receives only light from the backlight unit.

### DISCLOSURE OF INVENTION

A first aspect of the present invention provides a light sensing system comprising: a first light sensor disposed on a substrate; a second light sensor disposed on the substrate; a first light shielding layer disposed over the first light sensor but not over the second light sensor; a first electrically conductive material disposed between the first light shielding layer and the first light sensor; and a second electrically conductive material disposed over the second light sensor, the second electrically conductive material being at least partially transmissive; and wherein the first electrically conductive material and the second electrically conductive material are disposed on the substrate.

The term “disposed on a substrate” as used herein does not require that the component is disposed directly on the substrate, and does not exclude the possibility of there being one or more intervening layers between the component and the substrate.

Ambient light is detected by the second light sensor, which thus acts as a “light” sensor. The first light sensor is shielded from ambient light by the first light shielding layer, and thus acts as a “dark” sensor. Provided that the first light sensor is electrically well-matched to the second light sensor, and provided that the first light sensor is close to the second light sensor, the difference between the output of the first light sensor and the output of the second light sensor is thus a measure of the ambient light, since variations in temperature and stray light affect both sensors equally. By “electrically well-matched” is meant that the first and second light sensors are fabricated to have, to within the limits of manufacturing tolerance, the same layout, orientation, size, dimensions of the active region, doping of the active region etc, so that their electrical characteristics are as close to one another as possible. The first light sensor is placed close to the second light sensor so that variations in temperature and stray light affect both sensors equally, but it is not necessarily required that the two sensors are placed as close together as would be allowed by design rules and/or by the manufacturing process.

In order to provide accurate compensation for temperature and stray light, the “light” and “dark” photodiode structures must be electrically well-matched, producing an identical current-voltage characteristic across a range of temperatures. The inventors have realised that, in prior art light sensing systems that determine light intensity from the difference in output between a “light” photodiode and a “dark photodiode, providing a light shielding layer over the “dark” photodiode as shown in FIG. 6 or 7 introduces a parasitic capacitance Cₚ into the “dark” photodiode that is not present in the “light” photodiode. This is indicated in FIG. 9(b).

The parasitic capacitance Cₚ is set up between the light shielding layer and the active region of the “dark” photodiode structure, and means that the “dark” photodiode structure and the “light” photodiode structure of FIG. 9(b) are not electrically equivalent to one another. Accordingly, it cannot be assumed that the difference between the output of the “dark” photodiode structure of FIG. 9(b) and the output of the “light” photodiode structure of FIG. 9(b) arises solely from the ambient light incident on the “light” photodiode structure.

In contrast, in a light sensing system of the present invention the electrically conductive material disposed between the first light shielding layer and the first light sensor (the “dark” sensor) prevents any parasitic capacitance from being set up between the first light shielding layer and the active layer of the first light sensor. The electrical characteristics of the first light sensor are therefore well-matched to the electrical characteristics of the second light sensor, and a difference between the output of the “first light sensor and the output of the second light sensor (the “light” sensor) arises solely from the ambient light incident on the second light sensor

Providing the second electrically conductive material over the second light sensor ensures that the first light sensor and the second light sensor are as closely electrically matched as possible. By making the second electrically conductive material at least partially light-transmissive, the operation of the second light sensor is not significantly affected. (The required degree of light-transmissivity of the second electrically conductive material will depend on the nature of the second light sensor and on the intended application of the light-sensing system. In some applications it is preferable for the second electrically conductive material to be transparent or substantially transparent, but this is not always the case.)

It should be noted that the requirement that the second electrically conductive material at least partially light-transmissive need relate only to the intended wavelength, or wavelength range, of operation of the light-sensing system. In the case of a light-sensing system intended to detect ambient light, for example, it is sufficient if the second electrically conductive material is at least partially transparent over the visible wavelength range. Indeed, in some cases it may be advantageous if the second electrically conductive material has a low light-transmissivity outside the intended wavelength, or wavelength range, of operation of the light-sensing system—for example, in the case of a light-sensing system intended to detect ambient light it might be advantageous if the second electrically conductive material has a low transmissivity for UV light so that it was able to filter out an unwanted UV component in the incident light.

Similarly, in an embodiment in which the second electrically conductive material is transparent or substantially transparent, it is sufficient for the second electrically conductive material to be transparent or substantially transparent at the intended wavelength of operation, or over the intended wavelength range of operation, of the light-sensing system.

A second aspect of the present invention provides a display comprising a light sensing system of the first aspect.

Preferred features of the invention are set out in the dependent claims.

### BRIEF DESCRIPTION OF DRAWINGS

Preferred embodiments of the invention will now be described by way of illustrative example with reference to the accompanying figures in which:

FIG. 1 shows a prior art AMLCD with an integrated ambient light sensor;

FIGS. 2(a) and 2(b) show a prior art AMLCD with an integrated image sensor;

FIG. 3 shows a typical prior art AMLCD manufacturing process;

FIG. 4 shows a cross-section of a typical prior art AMLCD pixel;

FIG. 5 shows a cross-section of a typical prior art TFT and photodiode;

FIG. 6 shows a prior art photodiode with a light blocking layers above the photodiode;

FIG. 7 shows a prior art photodiode with light blocking layers above and below the photodiode;

FIG. 8 shows a prior art an ambient light sensor incorporating “light” and “dark” photodiode devices;

FIG. 9(a) shows the basic concept of a light sensor according to the invention;

FIG. 9(b) illustrates a problem with a prior art light sensor according to the invention;

FIG. 9(c) shows a modification of the embodiment of FIG. 9(a);

FIG. 10 shows dark current-voltage characteristics of prior art photodiodes and of a photodiode of the invention;

FIG. 11 illustrates the basic physical principles underlying this invention;

FIG. 12 illustrates a second embodiment of the invention;

FIG. 13 illustrates a third embodiment of the invention;

FIG. 14 illustrates a measuring circuit suitable for use with the invention;

FIG. 15 shows a timing chart describing the operation of the measuring circuit of FIG. 14;

FIG. 16 illustrates another measuring circuit suitable for use with the invention;

FIG. 17 shows a timing chart describing the operation of the measuring circuit of FIG. 14;

FIG. 18 illustrates another measuring circuit suitable for use with the invention; and

FIG. 19 illustrates a display according to the invention.

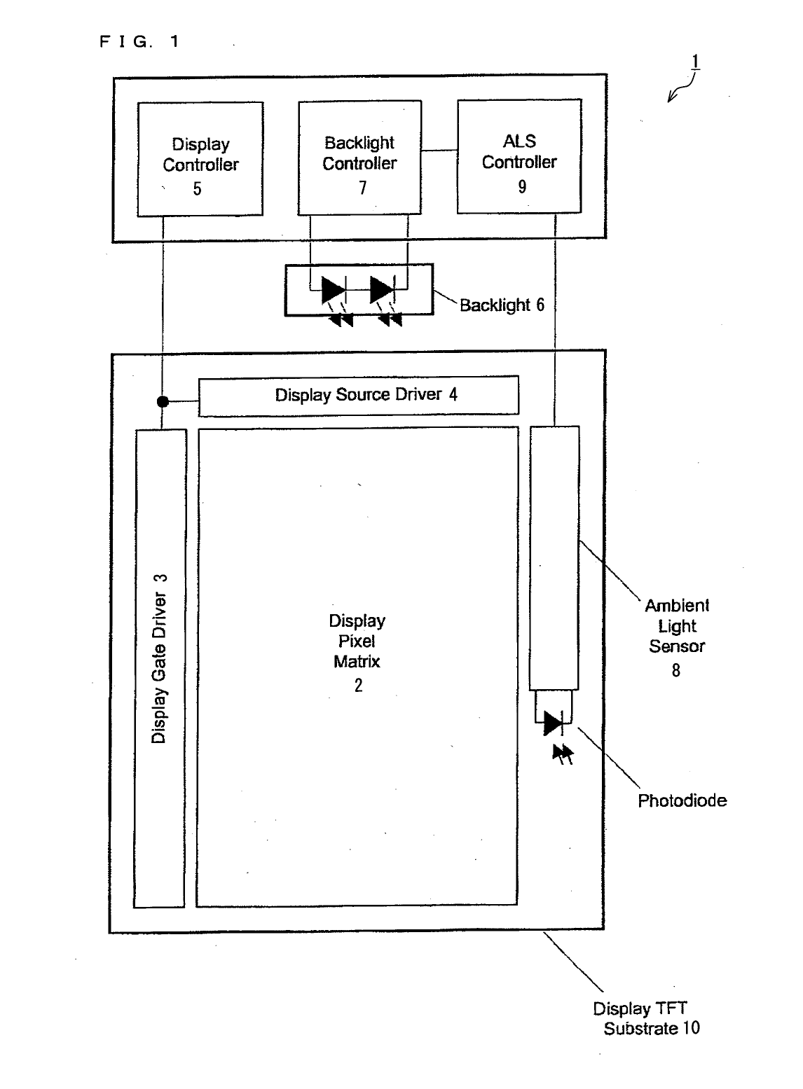

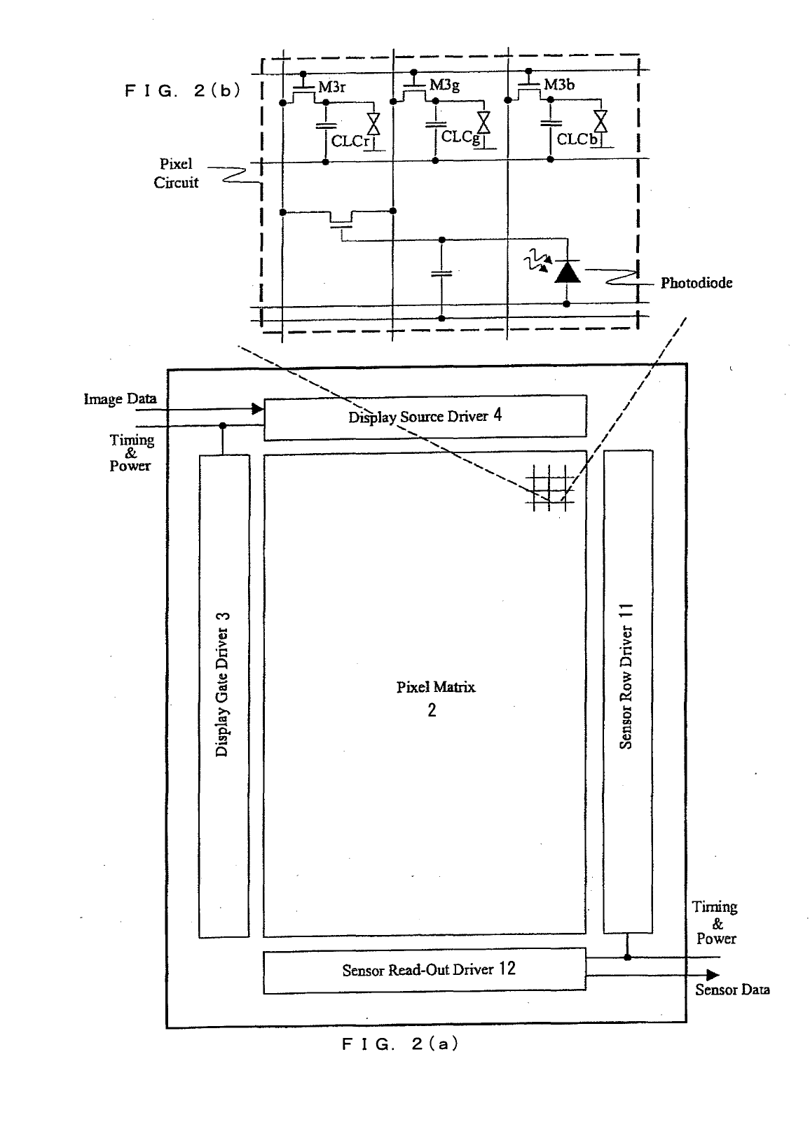

### BEST MODE FOR CARRYING OUT THE INVENTION

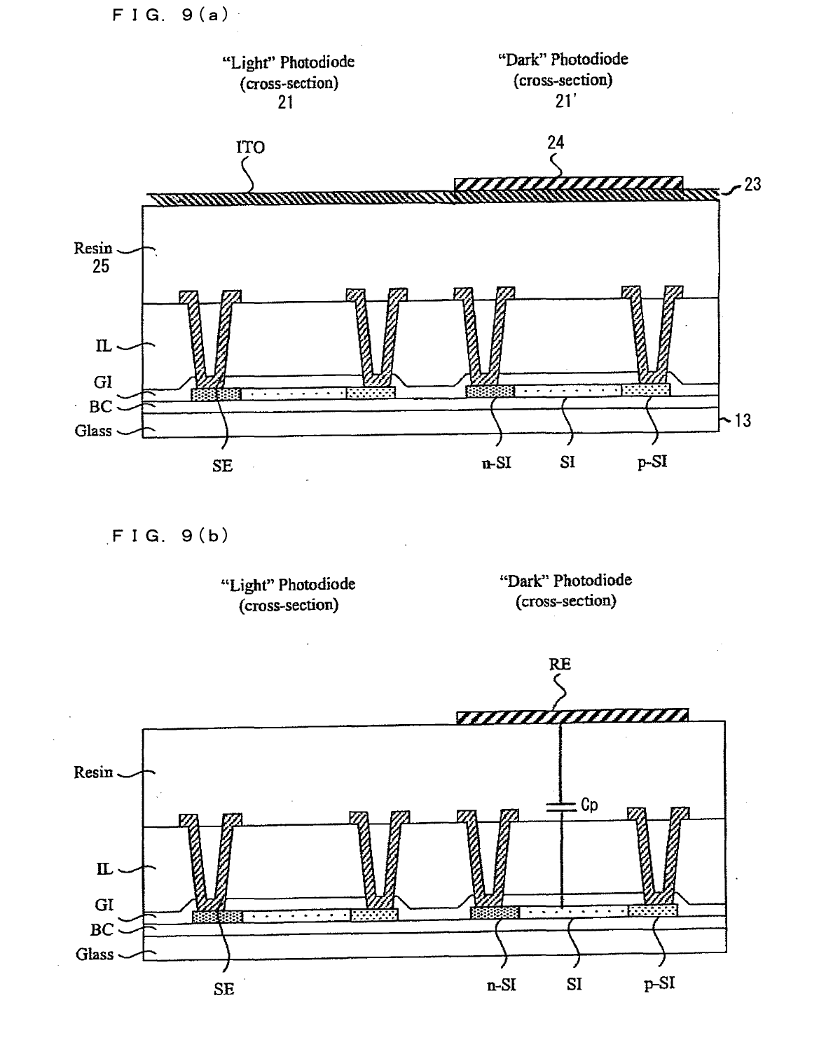

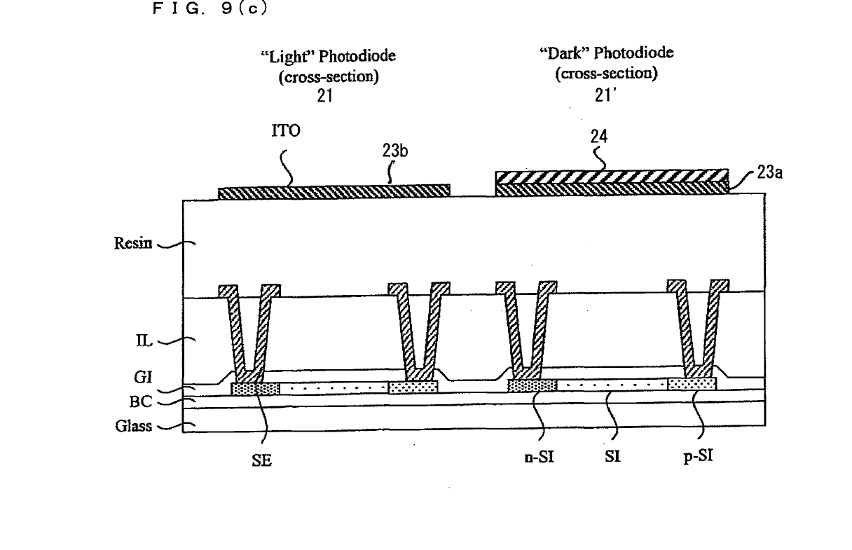

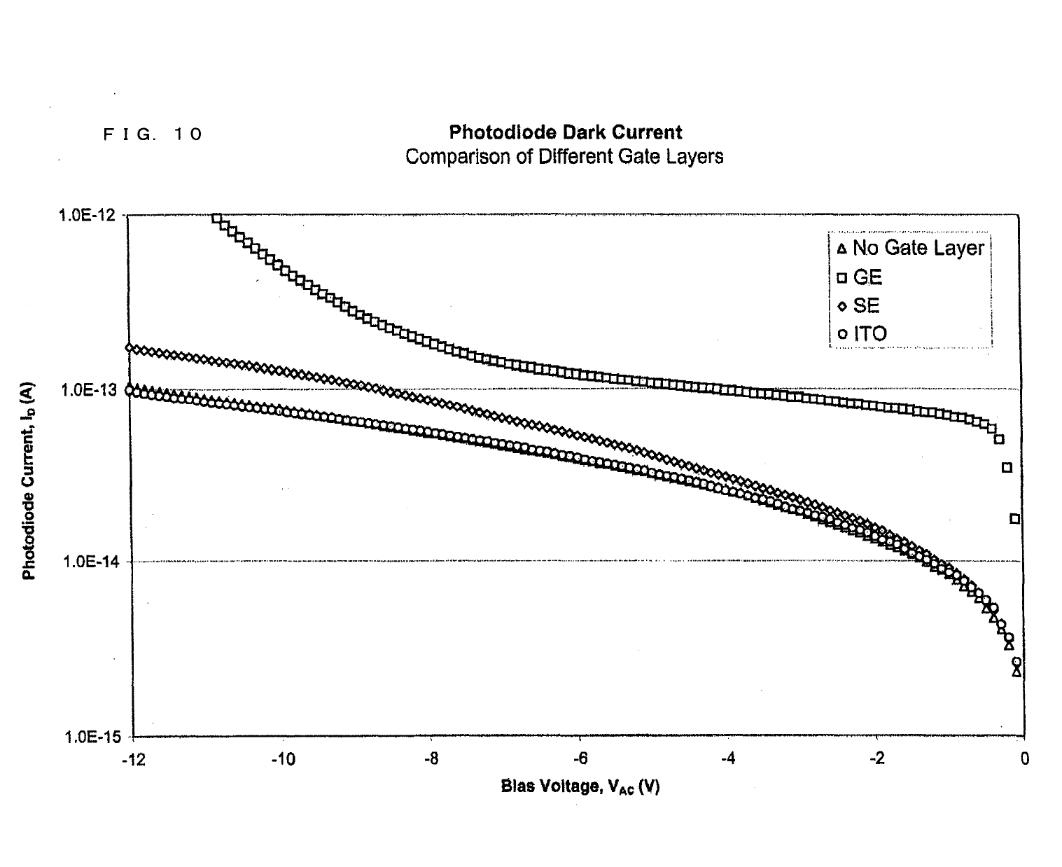

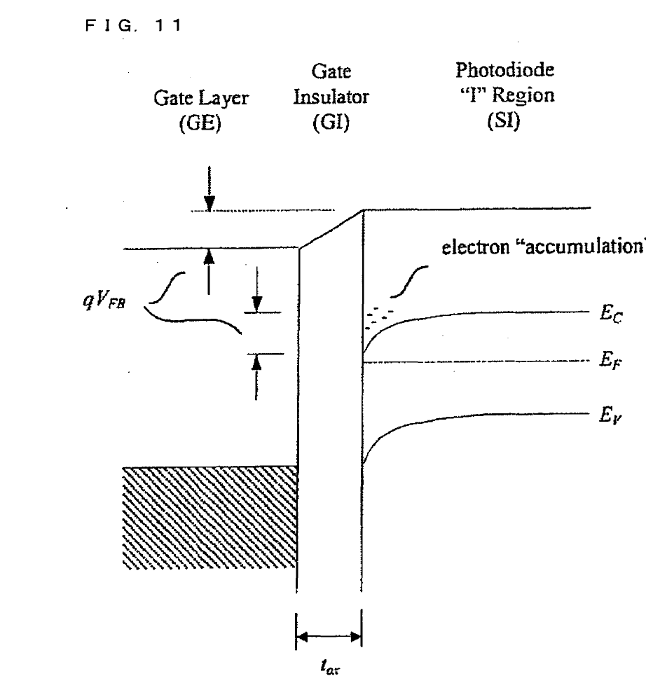

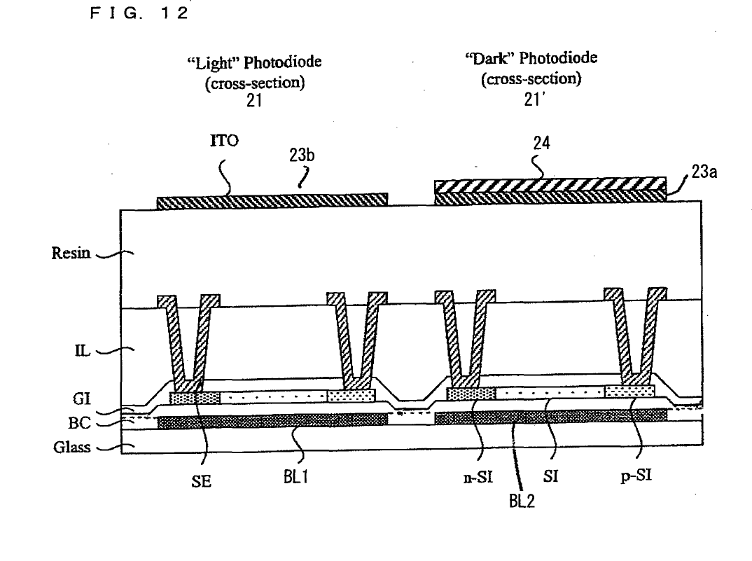

The inventors have realised that the addition of a conductive light-shielding layer, for example a gate structure, may significantly modify the electrical characteristics of a photodiode by introducing a parasitic capacitance Cₚ, as is indicated in FIG. 9(b). The effects of this are further explained with reference to FIG. 10, which shows the dark current in the photodiode as a function of the bias voltage across the photodiode. (The dark current is the current that flows in the photodiode in the absence of any ambient light.) In FIG. 10, the data points denoted by a “Δ” show the characteristics of a photodiode with no shielding layer or gate layer (such as, for example, the left hand transistor in FIG. 9(b)), the data points denoted by a “□” show the characteristics of a photodiode with a gate electrode disposed over, and close to, the active layer (such as, for example, the gate electrode 19 of FIG. 7), the data points denoted by a “⋄” show the characteristics of a photodiode with a source electrode that extends over the active layer (such as, for example, the gate electrode 19 of FIG. 7) no shielding layer or gate layer (such as, for example, the extended source electrode 15′ of FIG. 7), and the data points denoted by a “o” show the characteristics of a photodiode according to the present invention in which a transparent conductive layer is provided between the light shielding layer and the active layer. Apart from the differences in the light shielding layers, the photodiodes used to obtain the results of FIG. 10 were identical to one another.

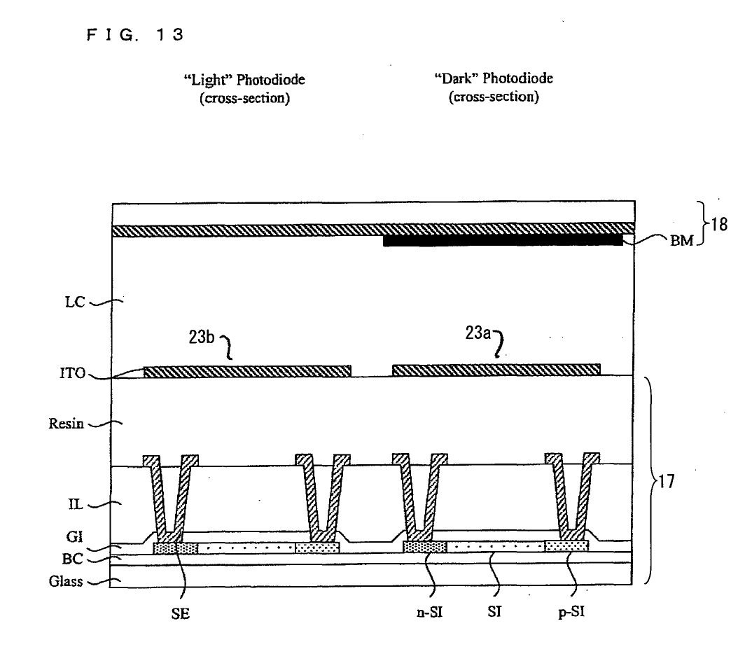

It can be seen that providing a gate electrode or a source electrode light as a light shielding layer has the effect of increasing the photodiode dark current, compared to a photodiode in which no light shielding layer is provided. The increase in photodiode dark current with the addition of a gate structure is thought to be due to the flat-band voltage shift induced by the difference in work-function between the gate material and the silicon in the “I” region of the photodiode structure. This difference in work function causes charge to accumulate in the photodiode “I” region and this consequently reduces the depletion region width. This is shown in FIG. 11, which is an illustration of the energy levels for a structure having a gate layer GE, a gate insulator layer G1, and an “I” region SI of a silicon photodiode. The gate layer GE is assumed to be a metallic layer, so that all electron states having energies below the Fermi level in the gate layer are occupied (indicated by diagonal shading) and electron states with energies above the Fermi level are unoccupied. The valence band edge and conduction band edge of the “I” region SI of the silicon photodiode are denoted by Eᵥ and E_{c} respectively. It can be seen that the valence band edge and conduction band edge of the “I” region of the photodiode “bend” near the interface between the “I” region and the gate insulator GI. The flat band voltage shift V_{FB} is the difference between, on the one hand, the actual value of the conduction band edge of the “I” region at the interface between the “I” region and the gate insulator GI and, on the other hand, the value that the conduction band edge would have had at the interface if no band-bending had occurred and the conduction band edge had stayed flat.

The reduction in depletion region width leads to a corresponding increase in the field across the depletion region and the photodiode dark current, which is directly related to this field, is increased. Both the vertical separation of the photodiode “I” region and the gate and the relative work-functions of the two materials determine the flat-band voltage shift and thus the increase in photodiode dark current.

In all the prior art described hereinabove, the photodiode includes a gate layer above at least a portion of the intrinsic region. As explained, the inclusion of this layer has a significant effect on the electrical field present in the intrinsic region with the result that the dark leakage current of the photodiode is increased compared to an identical device without the gate metallization layer. This high dark leakage current limits the sensitivity of the photodiode which is of particular concern for ambient light sensor or image sensor systems that must perform measurements of very low light levels.

The first embodiment of this invention describes the basic concept of this invention: the use of a transparent conductive layer to create a matched pair of “light” and “dark” photodiode structures. This embodiment will be described with reference to an example which uses thin-film photodiodes as the light sensors, but the invention is not in principle limited to this.

FIG. 9(a) shows a light sensing system according to a first embodiment of the present invention. As shown in FIG. 9(a), this light sensing system comprises two thin-film photodiode devices disposed on a substrate 13 (for example a glass substrate):
a first photodiode device 21, exposed to ambient light; and
a second photodiode device 21′, shielded from ambient light, which includes a light blocking layer 24 above the active region 14 of the photodiode. In this embodiment the light blocking layer is shown as a reflective electrode (RE), but the light blocking layer is not limited to this.

According to the present invention, a layer 23 of an electrically conductive material is disposed on the substrate 13, between the light shielding layer 24 and the active region of the dark photodiode device 21′. In the embodiment of FIG. 9(a) the layer 23 extends over substantially the entire area of the light sensing system and, in particular, extends over “light” photodiode device 21—and in such an embodiment the conductive layer 23 is at least partially light-transmissive so that operation of the “light photodiode” is not significantly affected. The conductive layer 23 is preferably transparent or substantially transparent so that it has little or no effect on the sensitivity to ambient light of the “light” photodiode 21 but, depending on the intended application of the light sensing system, full or near transparency of the conductive layer 23 may not be required. The layer 23 may be, for example, a layer of ITO (indium tin oxide).

As noted above, the requirement that electrically conductive layer 23 is at least partially light-transmissive need relate only to the intended wavelength, or wavelength range, of operation of the light-sensing system. Similarly, in an embodiment in which the electrically conductive layer 23 is transparent or substantially transparent, it is sufficient for the electrically conductive layer 23 to be transparent or substantially transparent at the intended wavelength of operation, or over the intended wavelength range of operation, of the light-sensing system.

The layer 23 of an electrically conductive material (hereinafter the “conductive layer, for convenience) is effective to suppress the parasitic capacitance C_{P} that occurs in the prior art device of FIG. 9(b). Effectively, the conductive layer 23 forms a “Faraday cage” that screens the active region of the “dark” photodiode 21′ from any electric field established by the light shielding layer (which is in general a metallic layer). As a result of the elimination of the parasitic capacitance C_{P} of FIG. 9(b), the electrical characteristics of the “light” photodiode 21 would be identical to the electrical characteristics of the “dark” photodiode 21′, assuming that physical characteristics of the “light” photodiode 21 are identical to the physical characteristics of the “dark” photodiode 21′. (It should be noted, however, that the present invention does not require the formation of a “Faraday cage” in the sense of providing immunity from electrical noise. The aim of the invention is to ensure that the electrical effects of the conductive light blocking layer placed over the “dark” photodiode in the prior art system of FIG. 9(b) are replicated in the “light” photodiode, so that the “light” photodiode and the “dark” photodiode are electrically matched or substantially matched.

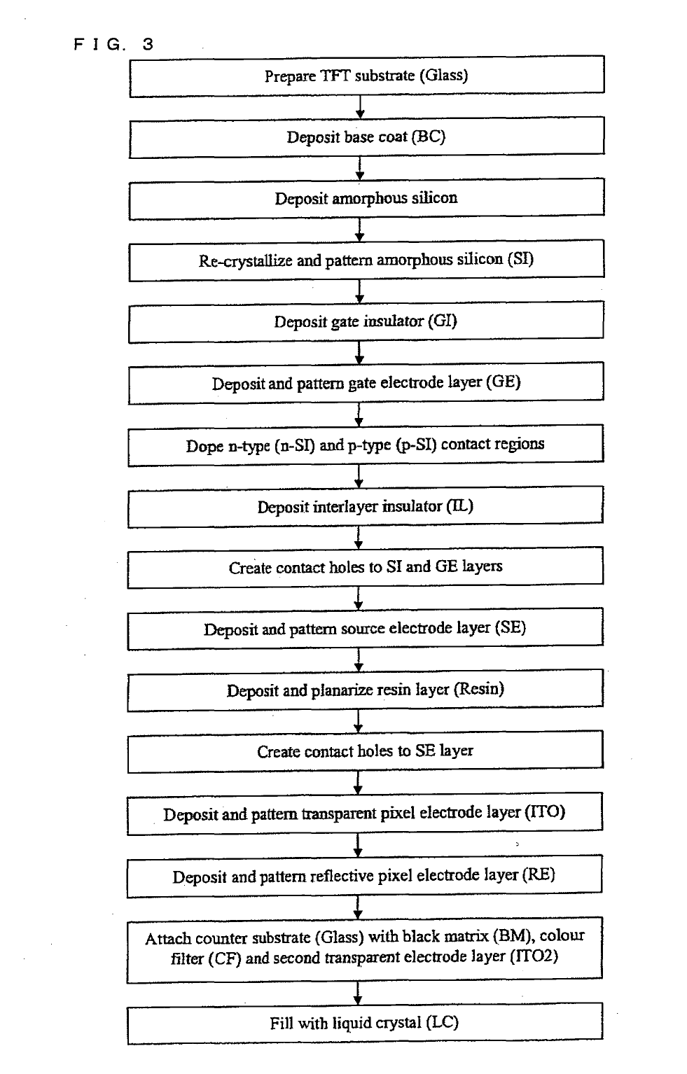

The layer 23 would in all practical cases be electrically connected to another component rather than floating. In principle the layer 23 could be connected to an external ground point in the circuit, to a terminal of one of the photodiodes (e.g., to the anode of one of the photodiodes or to the cathode of one of the photodiodes), or to a constant DC bias potential. If the layer 23 were electrically connected to the anode or cathode of one of the photodiodes, contacts from the layer 23 to the metal layer SE forming the source/drain of the photodiodes would be made by means of “through holes” cut through the resin layer 25. The through holes may be formed during the step “Create Contact Holes to SE Layer” in the flowchart of FIG. 3, at the same time as through holes are formed to allow electrical connection to be made to the source/drain of the photodiodes.

However, whilst it is generally preferable to connect the conductive layer 23 to some known and/or constant potential it is (in most cases) not necessary to do so in order to achieve an improvement over a prior art system in which no conductive layer is present over the “light” photodiode. In a case where the potential of the conductive layer 23 were allowed to float, the conductive layer 23 would assume some potential determined by the relative capacitances of that layer to other conductive layers in the structure. In many cases the “dominant” conductive layers affecting this potential will be the anode and the cathode of the photodiodes, and so this potential will be substantially similar for the “light” photodiode and the “dark” photodiode”—so that the electrical characteristics of the “light” photodiode 21 would, as desired, be made identical, or similar, to the electrical characteristics of the “dark” photodiode 21′.

Thus, by making the two photodiodes 21,21′ electrically well-matched to one another (by “electrically well-matched” is meant that the two photodiodes are fabricated to have, to within the limits of manufacturing tolerance, the same layout, orientation, size, dimensions of the active region, doping of the active region etc, so that their electrical characteristics are as close to one another as possible), positioning the two photodiodes close to one another so that there will be no significant difference in temperature or intensity of stray light between the two photodiodes, and providing the conductive layer 23 to suppress the parasitic capacitance of FIG. 9(b), it is possible to provide a light sensing system in which the difference between the output of the photodiode 21 and the output of the photodiode 21′ is a true measure of the ambient light incident on the photodiodes. Since the two photodiodes are electrically well-matched to one another, the difference between the output of these devices may be used to provide an accurate measure of light intensity that is free from the effects of temperature and process variation. Moreover, since both devices are subject to approximately the same level of stray light from the reverse side, the effects of this may be eliminated too.

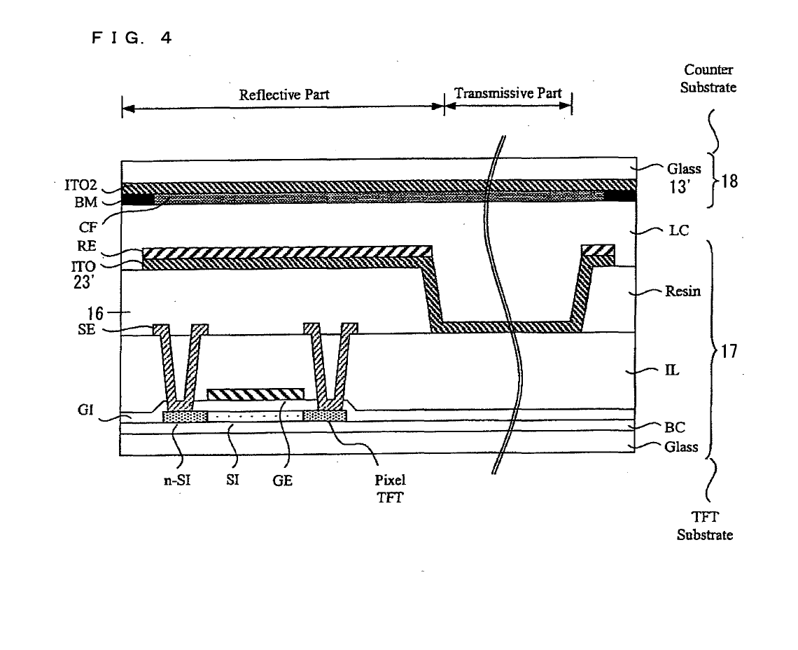

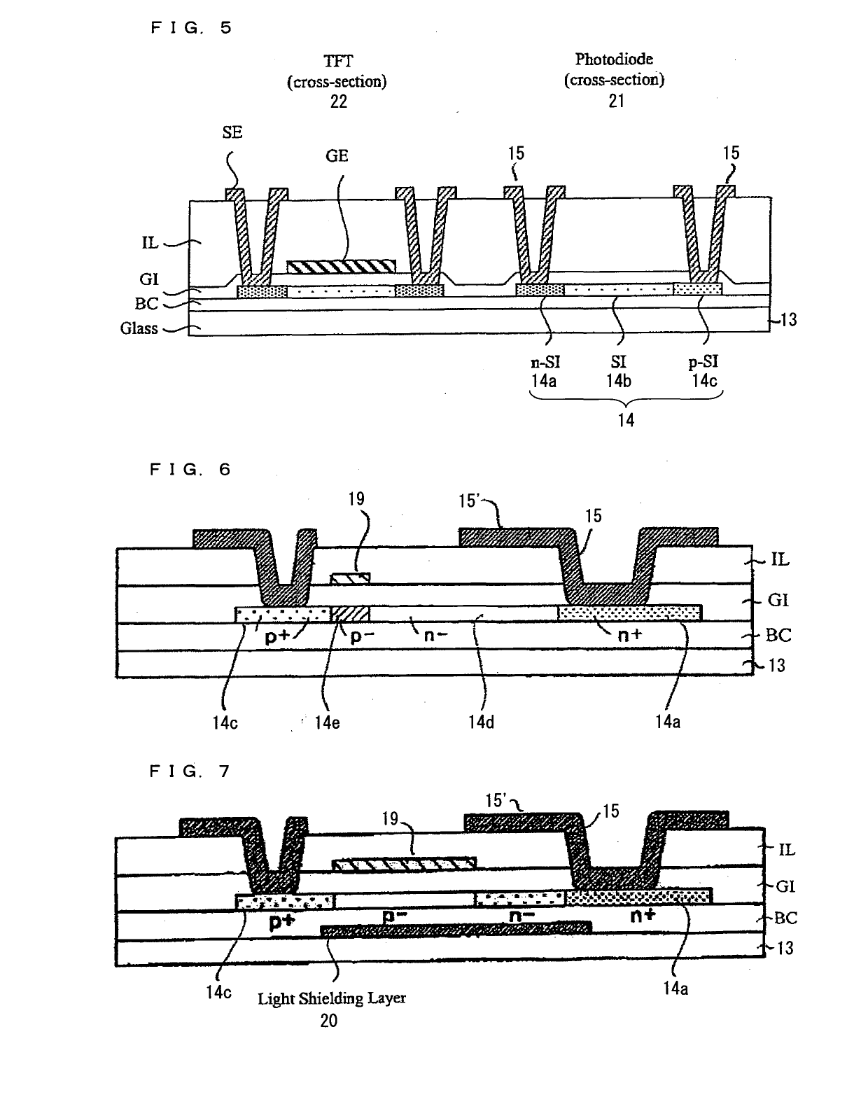

The light-sensing system of this embodiment may be fabricated in a standard thin-film transistor manufacturing process, the key steps of which are shown in the flowchart of FIG. 3. Fabrication of a typical AMLCD involves deposition of an ITO layer to form the transmissive parts of the display pixel electrodes, and this ITO layer may be used to form the conductive layer 23. In manufacture, an ITO layer may be deposited and patterned to form the transmissive parts of the display pixel electrodes, and the patterning step may be adapted to form the transparent conductive layer of FIG. 9(a) in addition to the display pixel electrodes. Similarly, fabrication of a typical AMLCD involves deposition of a metallic layer to form the reflective parts of the display pixel electrodes, and this metallic layer may be used to form the light shielding layer 24. In manufacture, a metallic layer may be deposited and patterned to form the reflective parts of the display pixel electrodes, and the patterning step may be adapted to form the light shielding layer 24 of FIG. 9(a) in addition to the display pixel electrodes. A typical display pixel structure is shown for reference in FIG. 4; the layer RE is a metallic layer that forms the reflective parts of the display pixel electrodes, and the ITO layer 23′ forms the transmissive parts of the display pixel electrodes.

A further feature of the embodiment of FIG. 9(a) is that the transparent conductive layer 23 and the light shielding layer 24 are provided over a resin planarising layer 25, which is provided over the interlayer insulator IL. (In practice, two or more resin layers may be provided, but a single resin layer is shown in FIG. 9(a) for convenience.) The light shielding layer 24 (and the transparent conductive layer 23) are therefore relatively far from the active region of the photodiode 21′, and are considerably further from the active region than either a conventional gate electrode (such as the gate electrode 19 of FIG. 7) or a light-shielding layer formed by a source metallisation (such as the source metallisation 15′ of FIG. 7). Even if the conductive layer 23 is not completely effective at screening the active region of the photodiode 21, the relatively large distance between the active region and the light shielding layer 24 will mean that any effect on the electrical characteristics of the photodiode 21′ is low. As FIG. 10 shows, a source metallisation such as the metallisation 15′ of FIG. 7 (denoted by “⋄”in FIG. 10) has a smaller effect on the electrical characteristics than does a gate electrode such as the gate electrode 19 of FIG. 7 (denoted by “□” in FIG. 10), and the increased distance of the source metallisation from the active region is an important factor in this.

The electrical characteristic of the photodiode 21′ of FIG. 9(a) in which an ITO layer is provided between the active region and the light shielding layer is shown in FIG. 10 by the “o” symbols. It can be seen that this is very close to the electrical characteristic of a photodiode in which no light shielding layer is present, denoted by the “Δ” symbols—in the invention, the current-voltage characteristic of the photodiode 21′ of FIG. 9(a) is significantly the same as the current-voltage characteristic of a photodiode without a gate layer.

To avoid an increase in the flat-band voltage between the conductive layer 23 and the “i” region of the photodiode active layer, “I” region, the conductive layer 23 should be connected to a voltage that is close to ground potential. Alternatively, the conductive layer 23 may be connected to either of the photodiode anode or cathode terminals.

In FIG. 9(a) the conductive layer 23 is shown as extending continuously over and between both photodiodes 21,21′. The invention is not, however, limited to this and it is possible for a first region 23a of electrically conductive material to be provided on the substrate under the light shielding layer 24, and for a second region 23b of electrically conductive material to be provided on the substrate over the “light” photodiode 21. This is shown in FIG. 9(c). (The description of components of FIG. 9(c) that correspond to components of FIG. 9(a) will not be repeated.) In this embodiment, the second region 23b of electrically conductive material provided over the “light” photodiode 21 is at least partially light-transmissive, and preferably transparent or substantially transparent, so that it has little or no effect on the sensitivity to ambient light of the “light” photodiode 21. However, the first region 23a of conductive material to be provided under the light shielding layer 24 is, in principle, not required to be transparent or substantially transparent or even light-transmissive so that the first region 23a of conductive material may in principle be made a different material from the second region 23b of electrically conductive material (although, in practice, use of different materials for the first and second regions 23a, 23b of conductive material would require additional fabrication steps).

The regions 23a, 23b would in all practical cases be electrically connected to another component rather than floating. As explained above, in principle they could be connected to an external ground point in the circuit, to the anode of one of the photodiodes or to the cathode of one of the photodiodes, or to a constant DC bias potential. However, as also explained above, in many cases the regions 23a, 23b may in principal be allowed to float,

In FIG. 9(c) the first region 23a of conductive material is shown as having the same size and shape as the light shielding layer 24 so that the first region 23a of conductive material is exactly co-extensive with the light shielding layer 24. The embodiment of FIG. 9(c) is not however limited to this, and the first region 23a of conductive material is not required to have the same size and shape as the light shielding layer 24 provided that it forms an effective Faraday cage.

The layer 23 of conductive material in FIG. 9(a) and the first and second regions 23a,23b of conductive material in FIG. 9(c) are shown as continuous, with a uniform thickness. The invention is not however limited to this. For example, it is known that a Faraday cage may be formed using a conductive mesh, and the present invention may in principle be effected by making the layer 23 of conductive material in FIG. 9(a) or the first and second regions 23a,23b of conductive material in FIG. 9(c) as a conductive mesh (although, in practice, deposition of conductive material as continuous region(s) is likely to prove the easiest fabrication method.)

In FIGS. 9(a) and 9(c) the light shielding layer 24 is shown disposed directly on the conductive layer 23 or the first region 23a of conductive material. The invention is not however limited to this and, in principle, there could be one or more intervening layers between the light shielding layer 24 and the conductive layer 23 or the first region 23a of conductive material. Moreover, although the conductive layer 23 or the first region 23a of conductive material is shown in FIGS. 9(a) and 9(c) as disposed directly on the resin planarising layer 25 there could, in principle, be one or more intervening layers between the conductive layer 23 or the first region 23a of conductive material and the resin planarising layer 25.

When the light sensing system of FIG. 9(a) or 9(c) is incorporated in a display device, the structure shown in FIG. 9(a) or 9(c) may form one substrate of the display device. For example where the structure comprises display pixel electrode (for example manufactured as described above with reference to FIG. 9(a)), the structure shown in FIG. 9(a) or 9(c) may constitute an active matrix substrate which may be disposed opposite a counter substrate with a liquid crystal layer disposed between the counter and the active matrix substrate in the manner shown generally in FIG. 4.

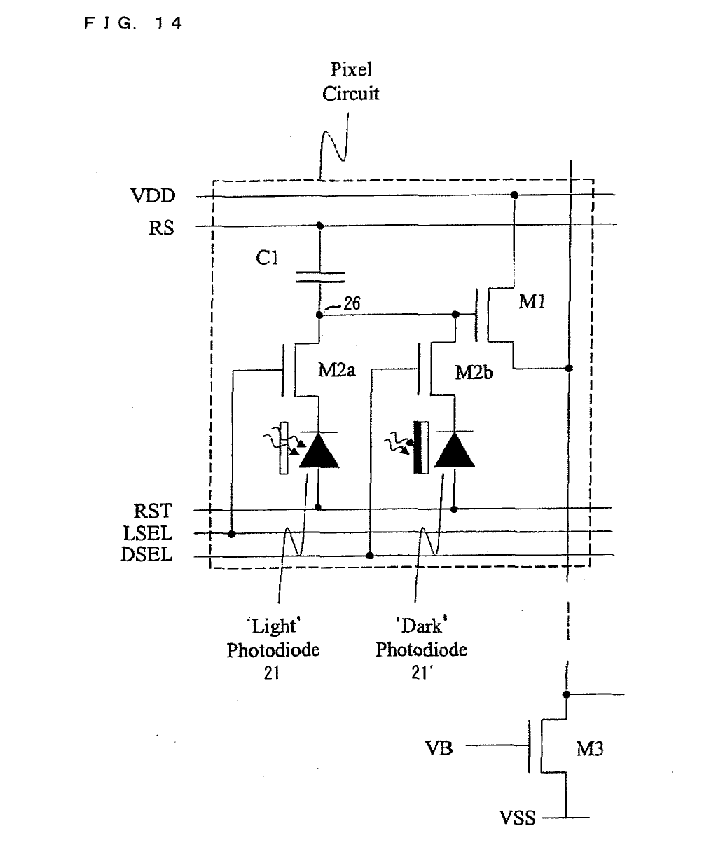

In a second embodiment of this invention, the matched photodiode structure described in the first embodiment is combined with the use of a second light blocking structure, BL1,BL2, to block the light incident from a display backlight located beneath the substrate 13 display TFT substrate. FIG. 12 is a cross-sectional view of a light sensing system according to a second embodiment of the invention, incorporating such a second light-blocking structure. The embodiment of FIG. 12 corresponds, part from the second light-blocking structure, to the embodiment of FIG. 9(a), and the description of components of FIG. 12 that correspond to components of FIG. 9(a) will not be repeated.) As shown in FIG. 12, both the “dark” and “light” photodiode structures include this second light blocking structure and are therefore electrically matched. The second light blocking structure, BL1,BL2 may be formed from any suitable opaque material and may, for example, be formed of a metal.

Apart from the provision of the second light blocking structure, BL1,BL2 the embodiment of FIG. 12 corresponds generally to that of FIG. 9(c); description of the features of the embodiment of FIG. 12 that are common with the embodiment of FIG. 9(c) will not be repeated.

An advantage of this embodiment is that the effect of stray light from the display backlight is minimised.

FIG. 12 shows a separate rear light blocking structure BL1,BL2 provided behind each photodiode 21,21′. The embodiment is not limited to this, and it would alternatively be possible to provide a continuous rear light-blocking structure that extends behind and between both photodiodes 21,21′ as indicated in broken lines in FIG. 12.

FIG. 12 shows the rear light blocking structure applied to the embodiment of FIG. 9(c), but it is not limited to this and may be applied to other embodiments such as, for example the embodiment of FIG. 9(a).

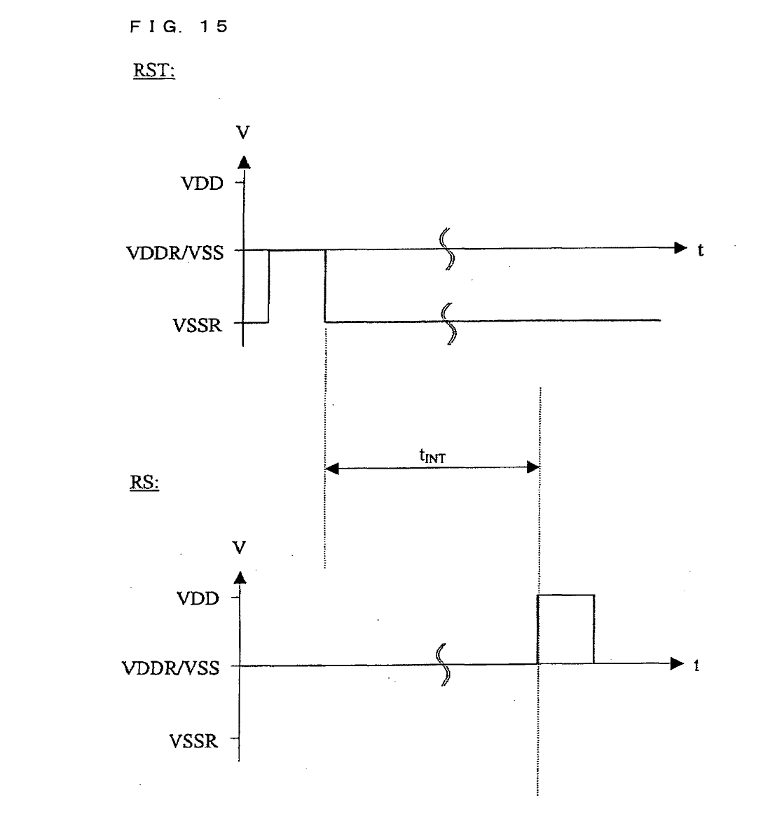

In the embodiments of FIGS. 9(a), 9(c) and 12, the light blocking layer 24 is disposed on the same substrate 13 as the photodiodes 21,21′. The invention is not however limited to this. In a further embodiment, shown in FIG. 13, the light-blocking layer 24 of the “dark” photodiode is not disposed on the same substrate as the photodiodes 21,21′.

FIG. 13 is a cross-sectional view through a display device, comprising an active matrix substrate 17, a counter substrate 18, and a liquid crystal layer LC disposed between the active matrix substrate 17 and the counter substrate 18. The photodiodes 21,21′ are disposed on the active matrix substrate 17, and the light shielding layer for shielding the “dark” photodiode 21′ is disposed on the counter substrate 18. Fabrication of a typical AMLCD may involve deposition of an opaque layer, for example a metallic layer BM, over the counter substrate to form a “black matrix” that improves the display image quality by preventing unwanted reflections from circuits around the periphery of pixel portions of the display (or that, in a transmissive display, prevents light passing through non-pixel portions of the display), and this opaque layer BM may be used to form the light shielding layer for shielding the “dark” photodiode 21′ thereby avoiding the need to provide a separate light-shielding layer. In manufacture, a metallic layer or other opaque layer may be deposited over the counter substrate and patterned to form the black matrix, and the patterning step may be adapted to form the light shielding layer of FIG. 13, in addition to the black matrix, from the opaque layer BM.

In the embodiment of FIG. 13, the active matrix substrate corresponds generally to the active matrix substrate shown in FIG. 9(c) (apart from the omission of the light shielding layer 24 of FIG. 9(c)) and its description will not be repeated. The counter substrate 18 of FIG. 13 comprises, in addition to the light shielding layer, a counter electrode 26 disposed over a substrate 13′.

The embodiment of FIG. 13 may alternatively be applied to a device having a layer 23 of electrically conductive material extending over both the light and dark photodiodes, as in FIG. 9(a).

The embodiment of FIG. 13 may be used, for example, in AMLCD devices which are transmissive only and which therefore do not include pixel reflective electrodes on the active matrix substrate.

A light sensing system of the present invention provides a first output, from the “light” photodiode 21, determined by ambient light, stray light, ambient temperature etc, and a second output, from the “dark” photodiode 21′, determined by stray light, ambient temperature etc. The difference between the output of the “light” photodiode 21 and the output of the “dark” photodiode 21′ is indicative of the level of ambient light incident of the “light” photodiode, and a light sensing system of the invention preferably further means for generating a signal indicative of the difference between the output of the “light” photodiode 21 and the output of the “dark” photodiode 21′.

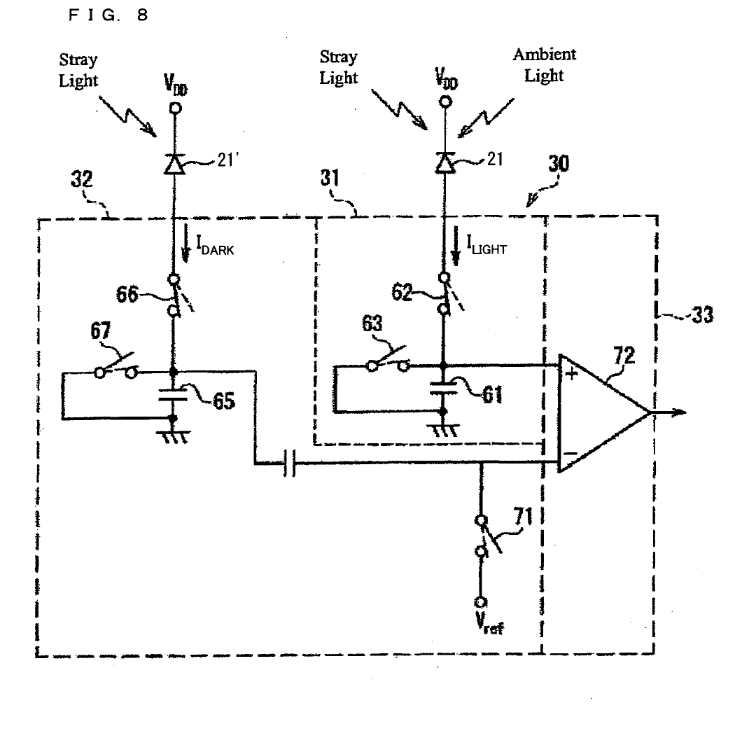

One suitable circuit for generating a signal indicative of the difference between the output of the “light” photodiode 21 and the output of the “dark” photodiode 21′ is a circuit of the type disclosed in JP2005-132938 and shown in FIG. 8.

The circuit 30 of FIG. 8 comprises a first input for receiving a generated current I_{light} from the “light” photodiode 21 and a second input for receiving a generated current I_{dark} from the “dark” photodiode 21′. The circuit 30 performs “I-to-V” conversion and generates an output voltage from the two input generated currents.

The circuit 30 comprises:
A part 31 to convert the current from the “light” photodiode to a voltage and a part 32 to convert the current from the “dark” photodiode to a voltage.
A comparator 33 to compare the output of the “dark” and “light” I-to-V conversion circuits.

The circuit 30 operates as follows
During a first reset phase switches 63 and 67 are closed and the “light” and “dark” integration capacitors 61 and 65 are reset to ground potential. During this phase switch 71 is also closed such that the negative terminal of the comparator 72, Vᵢₙ−, is initialised to a reference voltage, V_{ref}.
During a second integration phase, switches 63, 67 and 71 are opened and switches 62 and 66 are closed. The currents from the “light” and “dark” photodiodes are now integrated on the integration capacitors 61 and 65 respectively such that the voltages at the positive and negative input terminals of the comparator 72 begin to rise. The voltages at the input terminals of the comparator during this integration phase are given by:

Vᵢₙ+=I_{light}·t/Cᵢₙₜ

Vᵢₙ−=V_{ref}+I_{dark}·t/Cᵢₙₜ

where I_{light} and I_{dark} are the currents from the “light” and “dark” photodiodes respectively; and Cᵢₙₜ is the size of the integration capacitors 61, 65. The voltage at the negative input of the comparator 72 therefore begins the integration period at a higher value than the positive terminal but increases at a slower rate.
Accordingly, the output of the comparator 72 at the end of the integration period is sampled to generate a 1-bit digital measure of the relative magnitude of the “light” and “dark” photodiode currents. This measure of the incident light intensity on the “light” photodiode 21 is free from the effects of temperature, stray light and process variation.

By performing multiple integration periods with different values of the reference voltage V_{ref}, or with different values of the integration time tᵢₙₜ, for each period a more accurate measurement of the incident light intensity may be made. Alternatively, a plurality of comparator circuits, each with a different reference voltage, may be integrated onto the display substrate. The output currents from a pair of photodiodes may be sent to each of the plurality of comparator circuits, and a combination of the results from this plurality of circuits will provide a more accurate measure of the incident light intensity.

A significant advantage of this invention over the prior art is that the final output is, owing to the provision of the conductive layer 23, indicative of the incident light intensity on the “light photodiode” and is free from the effects of temperature, stray light and process variations.

In principle, the photodiode structures of the first, second or third embodiments are not limited to being used in only with the particular comparator circuit 30 of FIG. 8. Any suitable comparator circuit may be used to obtain a signal indicative of the difference between the output of the “light” photodiode 21 and the output of the “dark” photodiode 21′. Anyone skilled in the art should be able to apply the basic concept of this invention to other, known types of ambient light sensor circuit.

A light sensing system of the present invention may be used as an ambient light sensor, by arranging the photodiodes so that the “light” photodiode 21 receives ambient light. A light sensing system of the present invention is not however limited to use as an ambient light sensor. A further embodiments of the present invention provides an image sensor active pixel circuit containing a light sensing system of the present invention (for example a light sensing system according to any of FIG. 9(a), 9(c), 12 or 13). An image sensor active pixel circuit containing a light sensing system of the present invention is shown in FIG. 14.

The image sensor active pixel circuit of FIG. 14 is based on the 1 transistor pixel circuit developed by Sharp Kabushiki Kaisha and described in co-pending UK patent application Nos. 0611537.2 and 0611536.4.

The circuit of this embodiment comprises: an active pixel image sensor circuit in which the reset operation is achieved via the photodiodes 21,21′ operating in forward conduction and the row select operation is achieved by charge injection across the integration capacitor. The components enclosed by the broken lines in FIG. 14 are the components for one pixel of a display, which inter alia comprises “dark” and “light” photodiode structures 21′,21 and a pair of switches M2a,M2b (for example formed by thin film transistors (TFTs)) to select either the “dark” photodiode 21′ or the “light” photodiode 21. The gate of the switch M2a connected to the “light” photodiode is connected to a control line carrying a control signal LSEL, and the gate of the switch M2b connected to the “dark” photodiode is connected to a control line carrying a control signal DSEL. The transistor M3 is common to a column of pixels.

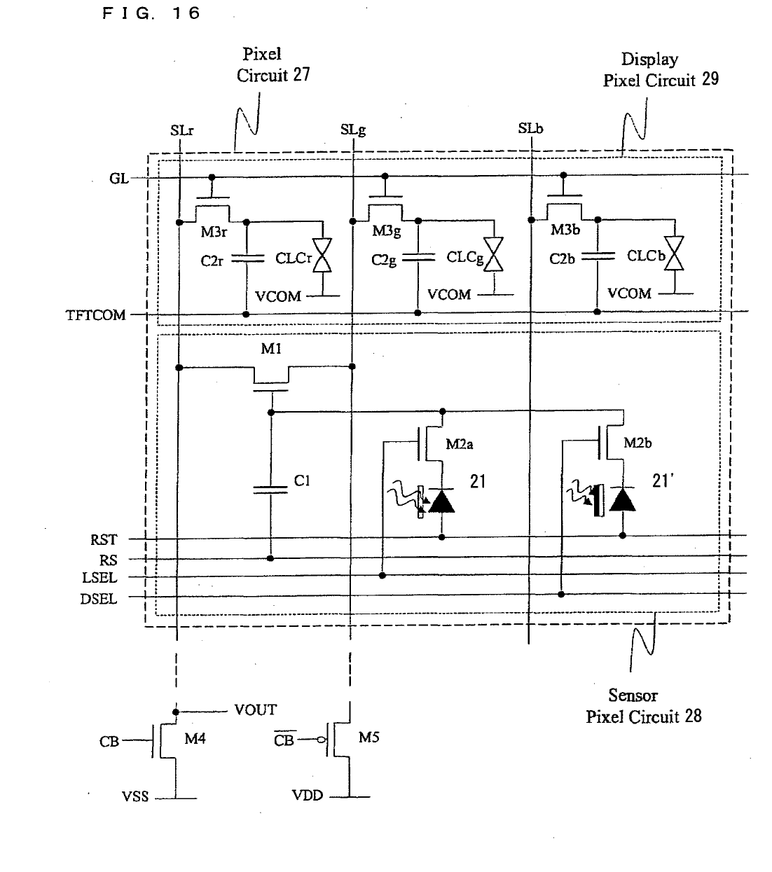

The operation of this embodiment is now described with reference to the schematic diagram of FIG. 14 and the waveform diagram of FIG. 15:
At the start of a first “dark” integration period switch M2b is closed by making signal DSEL high and switch M2a is opened by making signal LSEL low. The dark photodiode 21′ is therefore connected to the integration capacitor. The operation during this first integration period proceeds as follows:
The voltage of the integration capacitor 11 is now reset to an initial value by temporarily pulsing the reset signal RST. When the reset signal RST is brought high, the dark photodiode 21′ operates in forward conduction mode such that the integration node 26 is reset to a potential of:

V_{RST}=V_{DDR}−V_{D}

where V_{RST} is the reset potential of the integration node; V_{DDR} is the high signal level of the reset signal RST; and V_{D} is the forward voltage of the dark photodiode. The high potential of the reset signal, V_{DDR}, must be less than the threshold voltage of the source follower transistor M1 (which acts as an amplifier) such that it remains off during the reset and subsequent integration periods.
The first integration period begins when the reset signal RST is brought low. During the integration period, the output current from the “dark” photodiode current discharges the integration capacitor C1 at a rate proportional to the photon flux incident on the “dark” photodiode 21′. At the end of the integration period, the voltage of the integrating node 26 is:

V_{INT}=V_{DDR}−V_{D}−I_{PHOTO}·t_{INT}/C_{T}

where I_{PHOTO} is the current through the “dark” photodiode 21′; t_{INT} is the integration period; and C_{T} is the total value of capacitance of the integrating node (C_{T}=C_{INT}+C_{PD}+C_{TFT} where C_{INT} is the integration capacitor C1; C_{PD} is the parasitic capacitance of the photodiode and C_{TFT} is the parasitic capacitance of the transistor M1).
When a row of pixels is sampled, the row select signal RS is pulsed high. Charge injection occurs across the integration capacitor C1 such that the potential of the integrating node 26 is increased to:

V_{INT}=V_{DDR}−V_{D}−I_{PHOTO}·t_{INT}/C_{T}+(V_{RS,H}−V_{RS,L})·C_{INT}/C_{T}

where V_{RS;H} and V_{RS,H} are the high and low potentials of signal RS respectively.
The potential of the integrating node 26 is now raised above the threshold voltage of the source follower transistor M1 such that it forms a source follower amplifier with the bias transistor M3 located at the end of the pixel column. The output voltage of the source follower amplifier at this time is indicative of the current flowing in the “dark” photodiode integrated during the integration period.
At the end of the read-out period, signal RS is returned to a low potential and charge is removed from the integrating node 26 by injection across the integration capacitor C1. Accordingly, the potential of the integrating node drops below the threshold voltage of the source follower transistor M1 turning it off.
The output voltage of the source follower during the period in which signal RS is at a high potential may be used to charge a storage capacitor and be subsequently read-out in a manner similar to that disclosed in co-pending UK patent application Nos. 0611537.2 and 0611536.4. Such read-out means are well-known and are therefore not described further in this disclosure.
During a second “light” integration period switch M2a is closed by making signal LSEL high and switch M2b is opened by making signal DSEL low. The “light” photodiode 21 is therefore connection to the integration capacitor C1. The operation during this second integration period proceeds in a similar manner to that described above, except that it is now the “light” photodiode 21′ that resets and discharges the integrating node.
The difference between the output of the first and second integration periods may be used to generate a final output value.

The first and second integration periods described above may form a continuous cycle of operation. Alternatively, the first “dark” integration period may be performed only periodically to minimise the reduction in the sensor frame rate.

In FIG. 14, the drain of the source follower transistor M1 is connected to a voltage supply line VDD, while the source of the transistor M1 is connected to a source line. The line 6 is common to all of the sensor elements of the column and is connected to the column output and to the drain of a thin film insulated gate field effect transistor M3. The transistor M3 acts as a bias arrangement forming a source load for the transistor M1 and has a source connected to another voltage supply line VSS and a gate connected to a reference voltage source supplying a reference voltage VB.

The main advantage of this embodiment is the reduction in the fixed pattern noise of the image sensor. Since the “dark” and “light” photodiodes are electrically equivalent to one another, the difference between the output values of the first and second integration periods gives a measure of the incident light intensity free from the effects of temperature, stray light and process variation.

A key point is that the structures of the “dark” and “light” photodiodes are electrically equivalent to one another, including the parasitic capacitances. Therefore, under identical optical illumination conditions (i.e. under zero ambient illumination), the values generated by a pixel circuit during the row select operation will be identical in both the first and second integration periods.

An image sensor of the invention is not limited to the particular circuit of FIG. 14. A light sensing system of the invention may equally be applied to any other suitable type of image sensor active pixel circuit by a person skilled in the art.

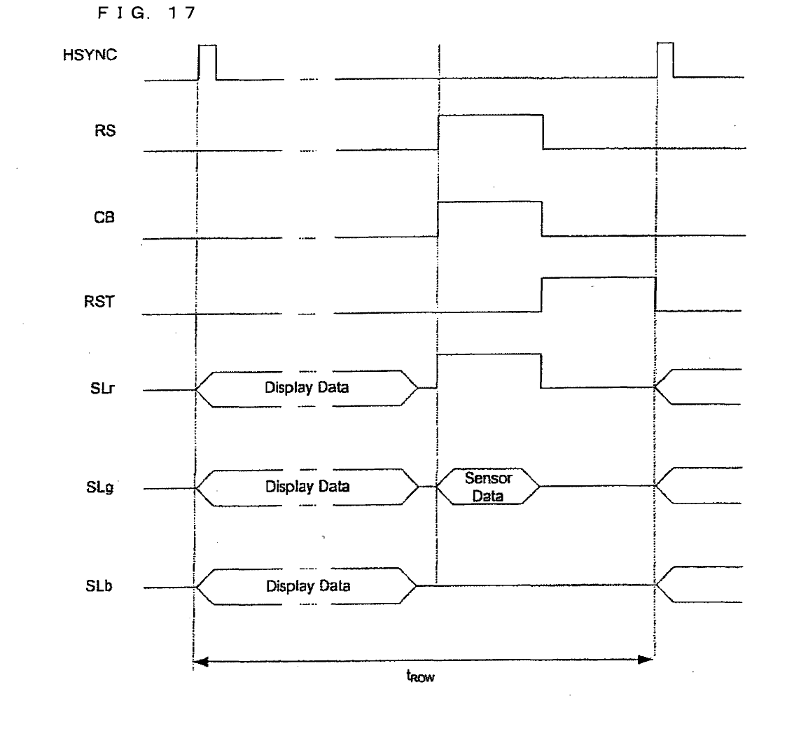

FIG. 16 shows a further embodiment of the invention in which shows a light sensing system and image display elements integrated within one AMLCD pixel. (The components enclosed by the broken lines in FIG. 16 are the components for one pixel.) The circuit of FIG. 16 is again based on the 1 transistor pixel circuit developed by Sharp Kabushiki Kaisha and described in co-pending UK patent application Nos. 0611537.2 and 0611536.4. This AMLCD pixel circuit 27 comprises:
an active pixel image sensor circuit 28 which, in this embodiment, corresponds to the circuit of FIG. 14; and;
an image display circuit 29.

The image display circuit 29 is shown as a full colour image display circuit comprising red, green and blue image display circuits 29R, 29G, 29B. Each of the red, green and blue image display circuits 29R, 29G, 29B comprises a pixel switch transistor M3r, M3g, M3b, a storage capacitor C2r, C2g, C2b, and a liquid crystal element CLCr, CLCg, CLCb. The operation of these display elements is well-known and is not described further in this disclosure.

FIG. 16 shows an embodiment in which the circuit of FIG. 14 is integrated together with display elements in the pixel of an AMLCD. The sensor read-out driver includes the column bias transistor M4 (which forms a source follower amplifier with the pixel source follower transistor) and VDD connection switch M5. The gate of column bias transistor M4 receives a reference voltage CB and the gate of column bias transistor M4 receives a reference voltage C̅B̅. The operation of the sensor read-out driver, including these devices, is disclosed in co-pending UK patent application Nos. 0611537.2 and 0611536.4.

The operation of the circuit of FIG. 16 is generally similar to the operation of the circuit of FIG. 14, in that there is a reset phase of resetting the voltage across the capacitor C1 followed by an integration phase in which the output voltage from one of the photodiodes (determined by which one of switches M2a and M2b is “open”) is applied to the capacitor C1. These are followed by a further reset phase and a further integration phase in which the output voltage from the other of the photodiodes is applied to the capacitor C1.

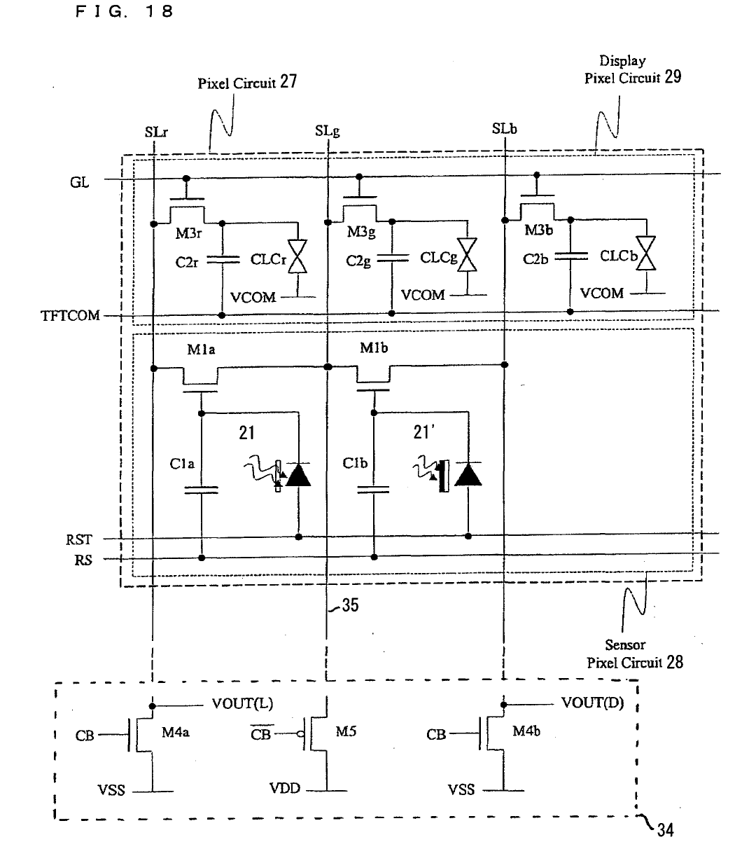

The timing chart of FIG. 17 illustrates how the display and sensor timing signals may be alternated to allow the sharing of common pixel matrix column lines.

A disadvantage of the embodiments of FIGS. 14 and 16 is that the size of the circuit associated with a pixel of a display device must increase to accommodate the additional switches and the matched photodiode structure. In particular, when the image sensor pixel circuit is integrated within a display pixel, as in FIG. 16, the increase in the size of the sensor circuit disadvantageously decreases the performance of the display. An additional disadvantage is that the image sensor frame rate must be decreased to allow the measurement of the “dark” signals.

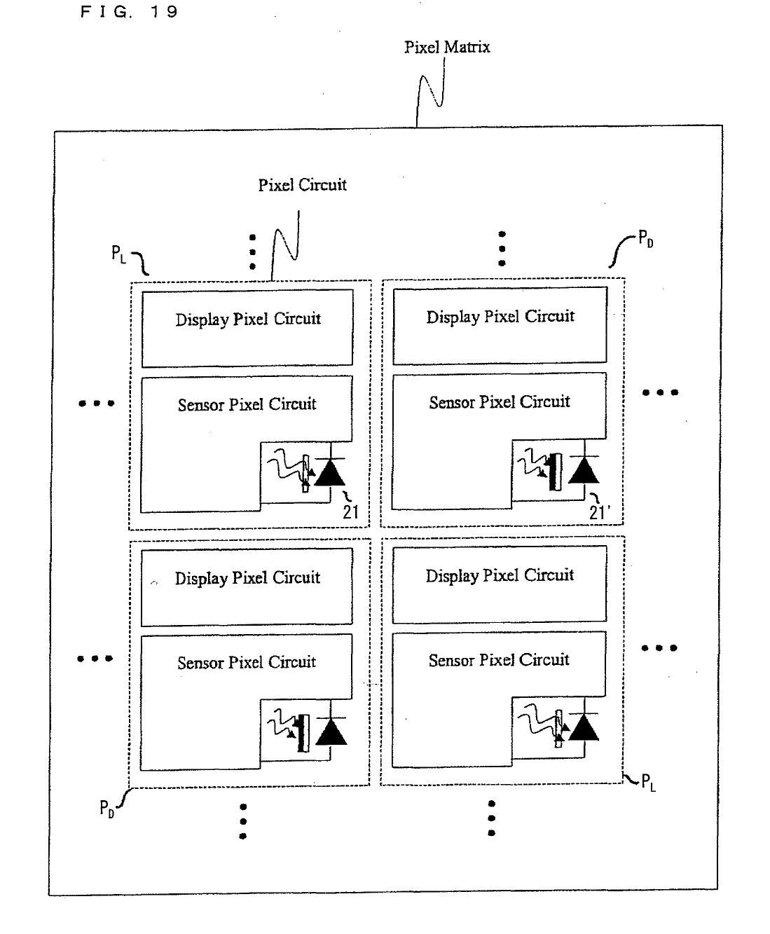

FIG. 18 shows a circuit diagram of a further embodiment which describes the integration of both a light sensing system of the invention, incorporating “light” and “dark” photodiodes and image display elements CLCr, CLCg, CLCb within one AMLCD pixel circuit 27. (The components enclosed by the broken lines in FIG. 18 are the components for one pixel). This circuit is provided with two integrating capacitors C1a,C1b, one for integrating (in an integrating phase) the output from one photodiode 21 and the other for integrating (in the integrating phase) the output from the other photodiode 21. In this embodiment:
The image sensor pixel circuit 28 consists of: “light” and “dark” photodiode structures 21,21′ as described above, respectively; a “light” source follower TFT; source follower transistors M1a, M1b whose gates are connected to the outputs of, respectively, the “light” and dark” photodiodes 21,21′; a “light” integration capacitor C1a; and a “dark” integration capacitor, C1b.
The display pixel circuit 29 of FIG. 16 corresponds to the display pixel circuit 29 of FIG. 18, and its description will not be repeated.

The circuit of FIG. 18 further comprises a sensor readout driver, denoted generally as 34. The sensor read-out driver 34 includes two column bias transistor M4a, M4b, arranged to form two separate “light” and “dark” source follower amplifiers with the pixel source follower transistors M1a, M1b. The pixel source follower transistor M1a, M1b are arranged to share a common drain connection such that one pixel matrix column line 36 may be used to supply the high power source VDD for both the “dark” and “light” source follower circuits. The sensor read-out driver 34 includes a connection switch M5 to supply this high power source during the sensor read-out period.

The timing chart of the previous embodiment (FIG. 17)) again illustrates how the display and sensor timing signals may be alternated to allow the sharing of common pixel matrix column lines.

An advantage of this embodiment is that the overall size of the image sensor pixel circuit is reduced compared to the previous embodiment. Although the image sensor pixel circuit of this embodiment includes one additional capacitor, one transistor and two pixel matrix row signal lines may be removed compared to the embodiment of FIG. 16. Additionally, since the “dark” and “light” output voltages are generated at the same time, no reduction in sensor frame rate is required.

A disadvantage of the embodiment of FIG. 16 and, to a lesser extent, the embodiment of FIG. 18 is that the size of pixel circuit must increase to accommodate the additional elements of the “dark” circuitry and the matched photodiode structure. A further embodiment provides a means of obtaining the benefits of the invention without increasing the size of the pixel circuit.

FIG. 19 is a schematic plan view of a display (or of a substrate of a display) according to this further embodiment. As shown in FIG. 19, the pixel matrix consists of pairs of alternate, matched “dark” and “light” pixels. Each “light” pixel P_{L} comprises a “light” photodiode 21 and each “dark” pixel P_{D} comprises a “dark” photodiode 21′. Each pixel (whether “dark” or “light”) comprises a display pixel circuit and a sensor pixel circuit 28 for determining the output of the photodiode in that pixel. The sensor pixel circuits 28 may be any suitable pixel circuit, for example a sensor pixel circuit as disclosed in co-pending UK patent application Nos. 0611537.2 and 0611536.4. Each pixel further comprises a display pixel circuit 29 including one or more image display pixels. The display pixel circuits 29 may be any suitable pixel circuit, and will not be described in detail.

A pair of matched pixels includes one “light” pixel P_{L} and one “dark” pixel P_{D}, and so includes “light” photodiode and one “dark” photodiode. The “light” pixel is formed where a photodiode with a transparent gate layer constitutes the pixel photodiode; the “dark” pixel is formed where a photodiode with a transparent gate electrode and light blocking layer forms the pixel photodiode.

Although the photodiodes constituting the matched pair of this embodiment are not as physically close as the previous embodiments—and may therefore not experience exactly similar temperature, stray light and process conditions—the pixel circuit dimensions are typically small enough as to make the difference negligible. This embodiment therefore still provides a differential output that provides a measure of the incident light intensity free from the effects of temperature, stray light and process variation.

1. A light sensing system comprising: a first light sensor disposed on a substrate; a second light sensor disposed on the substrate; a first light shielding material disposed over the first light sensor but not over the second light sensor; a first electrically conductive material disposed between the first light shielding layer and the first light sensor; and a second electrically conductive material disposed over the second light sensor, wherein the second electrically conductive material is at least partially light-transmissive; and wherein the first electrically conductive material and the second electrically conductive material are disposed on the substrate.

2. (canceled)

3. A light sensing system as claimed in claim 1 wherein the second electrically conductive material is transparent or substantially transparent.

4. (canceled)

5. A light sensing system as claimed in claim 1 wherein the second electrically conductive material is continuous with the first electrically conductive material.

6. (canceled)

7. A light sensing system as claimed in claim 1 wherein the first light shielding material is disposed directly on the first electrically conductive material.

8. A light sensing system as claimed in claim 1 and further comprising a second light shielding material disposed behind the first light source and a third light shielding material disposed behind the second light source.

9. A light sensing system as claimed in claim 8 wherein the second light shielding material is continuous with the third light shielding material.

10. A light sensing system as claimed in claim 1 and further comprising means for generating a signal indicative of the difference behind the output of the first light sensor and the output of the second light sensor.

11. A light sensing system as claimed in claim 10 wherein the means for generating a signal indicative of the difference behind the output of the first light sensor and the output of the second light sensor comprise: a first capacitor; a second capacitor; means for, in a reset period, resetting the voltage across the first capacitor and for resetting the voltage across the second capacitor; means for, in a reading period, supplying the output current from the first light sensor to the first capacitor; and means for, in the reading period, supplying the output current from the second light sensor to the second capacitor.

12. A light sensing system as claimed in claim 11 and comprising a first semiconductor amplifying element, the first capacitor having a first electrode which is connected to a control electrode of the first amplifying element and to an electrode of the first light sensor, and a second electrode connected to a control input, which is arranged to receive, during a sensing phase, a first voltage for disabling the first amplifying element and for permitting integration by the capacitor of a photocurrent from the first light sensor and to receive, during a reading phase, a second voltage for enabling the first amplifying element; and further comprising a second semiconductor amplifying element, the second capacitor having a first electrode which is connected to a control electrode of the second amplifying element and to an electrode of the second light sensor, and a second electrode connected to a control input, which is arranged to receive, during the sensing phase, a first voltage for disabling the second amplifying element and for permitting integration by the capacitor of a photocurrent from the second light sensor and to receive, during the reading phase, a second voltage for enabling the second amplifying element.

13.-15. (canceled)

16. A light sensing system as claimed in claim 1 wherein each light sensor is a photodiode.

17. A light sensing system as claimed in claim 16 wherein each light sensor is a p-i-n photodiode.

18. A light sensing system as claimed in claim 1 wherein the first electrically conductive material and the second electrically conductive material are electrically connected to a predetermined potential.

19.-20. (canceled)

21. A display comprising a light sensing system as defined in claim 1.

22.-23. (canceled)

24. A display as claimed in claim 21, wherein the display comprises a display medium disposed between first and second substrates, and wherein the first and second light sensors are disposed on the first substrate.

25. A display as claimed in claim 24 wherein the first light-shielding layer is disposed on the second substrate.
